(19) United States
(12) Patent Application Publication
(10) Pub. No.: US 2008/0084782 A1
(43) Pub. Date: Apr. 10, 2008

(54) DATA STORAGE DEVICE AND ITS CONTROLLING METHOD

(75) Inventor: Shinichi FUKADA, Hamura (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/867,936

(22) Filed: Oct. 5, 2007

(30) Foreign Application Priority Data
Oct. 6, 2006 (JP) 2006-275141

(51) Int. Cl. G11C 8/04

(52) U.S. Cl. 365/239

(57) ABSTRACT

A data storage device includes: a first nonvolatile memory section; a second nonvolatile memory section having a smaller memory capacity than the first nonvolatile memory section; a first write control section that performs a cyclic write control including sequentially writing received data to one-dimensionally arranged data areas in the first nonvolatile memory section from a start toward an end thereof, and again sequentially writing the received data from the start toward the end upon reaching the end; and a second write control section that performs a cyclic write control including obtaining given information for the received data as index information, linking the index information to write address information of the received data, sequentially writing the index information to one-dimensionally arranged data areas in the second nonvolatile memory section from a start toward an end thereof, and again sequentially writing the index information from the start toward the end upon reaching the end.

The entire disclosure of Japanese Patent Application No. 2006-275141, filed Oct. 6, 2006 is expressly incorporated by reference herein.

### BACKGROUND

1. Technical Field

The invention relates to data storage devices and methods for controlling the same.

2. Related Art

Data storage devices (data log devices) that continuously obtain and record data on temperatures, vibrations, brightness, sounds, images and the like are known, and such data storage devices are used in, for example, temperature management of foods, drive recorders, flight recorders, voice recorders, seismometers, and the like.

When an unpredicted event such as a failure or an accident occurs, data for a certain period of time preceding such an event must always be accumulated in order to keep a data log until the event occurs. When only data for a predetermined period of time immediately before the occurrence of an event needs to be accumulated, and old data preceding such a period can be successively overwritten, a memory device that is used for such purposes as described above can be formed as a ring buffer. An example of related art may be Japanese laid-open patent application JP-A-2005-259041.

Relatively simple data log devices may not have problems in handling data as the amount of data to be saved is small, but when a great amount of data needs to be saved, such as, in the case of storing histories of telephone communications, its handling is difficult. If the entire data is stored in a ring buffer, a memory with a large storage capacity needs to be used. Also, when necessary data is extracted from among the log data, a large amount of data needs to be handled, which is not effective and problematical.

### SUMMARY

In accordance with an aspect of an embodiment of the present invention, a data storage device is capable of storing a large amount of data in a form in which the data can be readily searched.

(1) A data storage device in accordance with an embodiment of the invention includes: a first nonvolatile memory section; a second nonvolatile memory section having a smaller memory capacity than the first nonvolatile memory section; a first write control section that performs a cyclic write control including sequentially writing received data to one-dimensionally arranged data areas in the first nonvolatile memory section from a start toward an end thereof, and again sequentially writing the received data from the start toward the end upon reaching the end; and a second write control section that performs a cyclic write control including obtaining given information for the received data as index information, linking the index information to write address information of the received data, sequentially writing the index information to one-dimensionally arranged data areas in the second nonvolatile memory section from a start toward an end thereof, and again sequentially writing the index information from the start toward the end upon reaching the end.

The index information may be information used for searching data body (received data) stored in the first nonvolatile memory section, such as, information extracted from the data body, or information not included in the data body but generated for searching the data body.

According to the embodiment of the invention, by searching the second nonvolatile memory section having a relatively small storage capacity, data stored in the first nonvolatile memory section of a large storage capacity can be retrieved. Accordingly, it is possible to provide a data storage device that is capable of storing a large amount of data in a readily searchable form by using a ring buffer.

(2) The data storage device in accordance with an aspect of the embodiment of the invention may further include an index information extracting section that extracts the given information as the index information from the received data based on index position information, wherein the second write control section performs a write control with the given information extracted from the received data as the index information.

(3) In the data storage device in accordance with an aspect of the embodiment of the invention, the second nonvolatile memory section may be formed from a ferroelectric memory.

(4) A method for controlling a data storage device equipped with a first nonvolatile memory section and a second nonvolatile memory section having a smaller memory capacity than the first nonvolatile memory section, the method including the steps of: performing a cyclic write control including sequentially writing received data to one-dimensionally arranged data areas in the first nonvolatile memory section from a start toward an end thereof, and again sequentially writing the received data from the start toward the end upon reaching the end; and performing a cyclic write control including obtaining given information for the received data as index information, linking the index information to write address information of the received data, sequentially writing the index information to one-dimensionally arranged data areas in the second nonvolatile memory section from a start toward an end thereof, and again sequentially writing the index information from the start toward the end upon reaching the end.

### BRIEF DESCRIPTION OF THE DRAWINGS

FIG. 1 is a functional block diagram of a data storage device in accordance with an embodiment of the invention.

FIG. 2 is a diagram for describing the structure of a first nonvolatile memory section and a second nonvolatile memory section in accordance with the embodiment of the invention.

FIGS. 3A and 3B are diagrams for describing data body and index information.

FIG. 4 is a block diagram of an example of a concrete device structure of the data storage device.

FIG. 5 is a flow chart of an example of operations of the data storage device.

### DESCRIPTION OF EXEMPLARY EMBODIMENTS

Preferred embodiments of the invention are described below with reference to the accompanying drawings. It is noted that the invention is not limited to the embodiments described below. Also, the invention includes embodiments provided by optionally combining the contents described below.

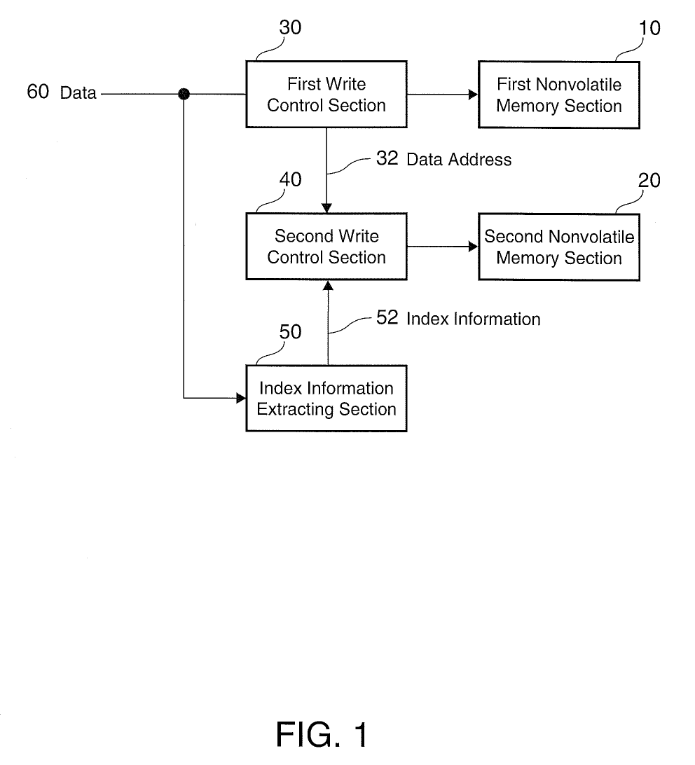

FIGS. 1-5 are drawings for describing a data storage device (data log device) in accordance with an embodiment of the invention.

FIG. 1 is a functional block diagram of the data storage device in accordance with the present embodiment.

The data storage device 1 in accordance with the present embodiment includes a first nonvolatile memory section 10.

A nonvolatile memory is a memory device in which stored data is not lost even when the power supply is cut off, in other words, a memory device that does not require external energy supply for retaining information. By using a nonvolatile memory, obtained information can be retained even when the supply of power is stopped. The nonvolatile memory may be realized by, for example, using a capacitor that uses electrical hysteresis.

The first nonvolatile memory section 10 may be realized by nonvolatile memories with a large capacity at low cost, such as, for example, flash EEPROM, or the like. These nonvolatile memories can be non-destructively read out, and do not have a limitation to the number of readout operations, but the number of rewriting operations is limited to about 1E5 times, and rewriting speed is low. Therefore, the nonvolatile memories described above may be suitable for the use in readout operations.

The data storage device 1 in accordance with the present embodiment includes a second nonvolatile memory section 20.

The second nonvolatile memory section 20 is a nonvolatile memory section having a smaller storage capacity than that of the first nonvolatile memory section, and may be formed from ferroelectric memories. It is noted here that the ferroelectric memory may be a memory with a memory element including ferroelectric material, and may be, for example, FeRAM. The ferroelectric memory may have a structure including a capacitor having ferroelectric material (ferroelectric capacitor). It is noted that the ferroelectric capacitor may have a structure comprised of opposing electrodes and ferroelectric material provided between the opposing electrodes. The ferroelectric material applicable to the invention may not be particularly limited, and may be, example, PZT ferroelectric material comprised of oxides containing Pb, Zr and Ti as constituent elements. Alternatively, as the ferroelectric material, any one of SBT, BST, BIT and BLT materials may be used.

It is noted that the ferroelectric memory may be understood as one type of nonvolatile memories in view of its characteristics.

FeRAM, a type of ferroelectric memory, is destructively read out, and therefore the number of its readout operations is limited, but the number of re-writing operations accounts for more than 1E10 times, and high-speed re-writing operations are possible. Therefore, FeRAM is a nonvolatile memory that is suitable to applications with a great number of re-writing cycles. Also, FeRAM may be more difficult to achieve a high degree of integration than flash EEPROM, and its cost may be higher than flash EEPROM.

In this respect, in accordance with the present embodiment, FeRAM may be used in the second nonvolatile memory section for storing index information having a smaller data size, and the first nonvolatile memory section for storing a large amount of data body may be realized with flash EEPROM of a large capacity. In this case, a data storage device without a concern about the upper limit in the number of rewriting cycles can be realized by forming the flash EEPROM with a considerably larger volume than that of the FeRAM.

The data storage device 1 in accordance with the present embodiment includes a first write control section 30. The first write control section 30 performs a cyclic write control including sequentially writing received data to one-dimensionally arranged data areas in the first nonvolatile memory section from a start toward an end thereof, and again sequentially writing the received data from the start toward the end when the end is reached. By performing the control described above, the first nonvolatile memory section can be functioned as a ring buffer.

Also, the data storage device 1 in accordance with the present embodiment includes a second write control section 40. The second write control section 40 performs a cyclic write control including obtaining given information for the received data as index information 52, linking the index information 52 to write address information of the received data, sequentially writing the index information to one-dimensionally arranged data areas in the second nonvolatile memory section from a start toward an end thereof, and again sequentially writing the index information from the start toward the end when the end is reached. By performing the control described above, the second nonvolatile memory section can be functioned as a ring buffer.

The index information 52 may be any information used for searching data body (received data) stored in the first nonvolatile memory section 10, such as, information extracted from the data body, or information not included in the data body but generated for searching the data body.

The data storage device 1 in accordance with the present embodiment includes an index information extracting section 50. The index information extracting section 50 performs a process of extracting given information as the index information from the received data based on index position information.

Information included in data for judging the importance of the data, the necessity of permanently storing the data and the like may be set as the index information. The position of the index information in the data may be set as index position information, whereby the index information may be extracted from among the data based on the index position information.

The second write control section 40 performs a write control, using the given information extracted from the received data as the index information.

When the memory area for index information is composed of the FeRAM that is used as a ring buffer like the present embodiment, index information that becomes unnecessary to be temporarily stored after a predetermined time has elapsed since the time it was written is successively overwritten. Accordingly, although the number of re-writing operations is increased, a relatively small memory area is sufficient for the operations described above, such that a data storage device in which information can be readily searched can be realized.

It is noted that the functions of the first write control section 30, the second write control section 40 and the index information extracting section 50 may be realized by software through, for example, executing a predetermined control program by the CPU, or a dedicated circuit may be used to realize the functions of the first write control section 30, the second write control section 40 and the index information extracting section 50.

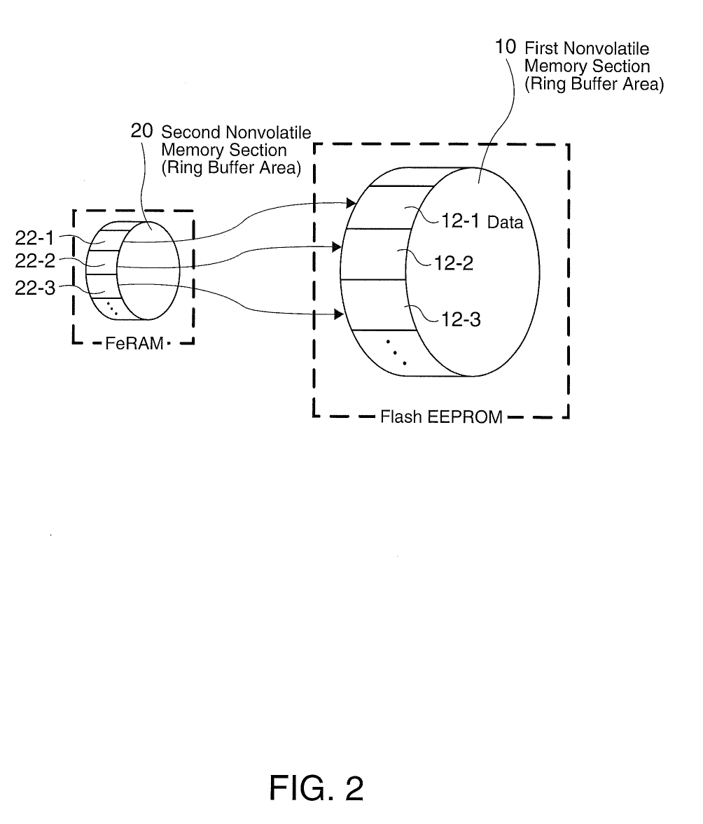

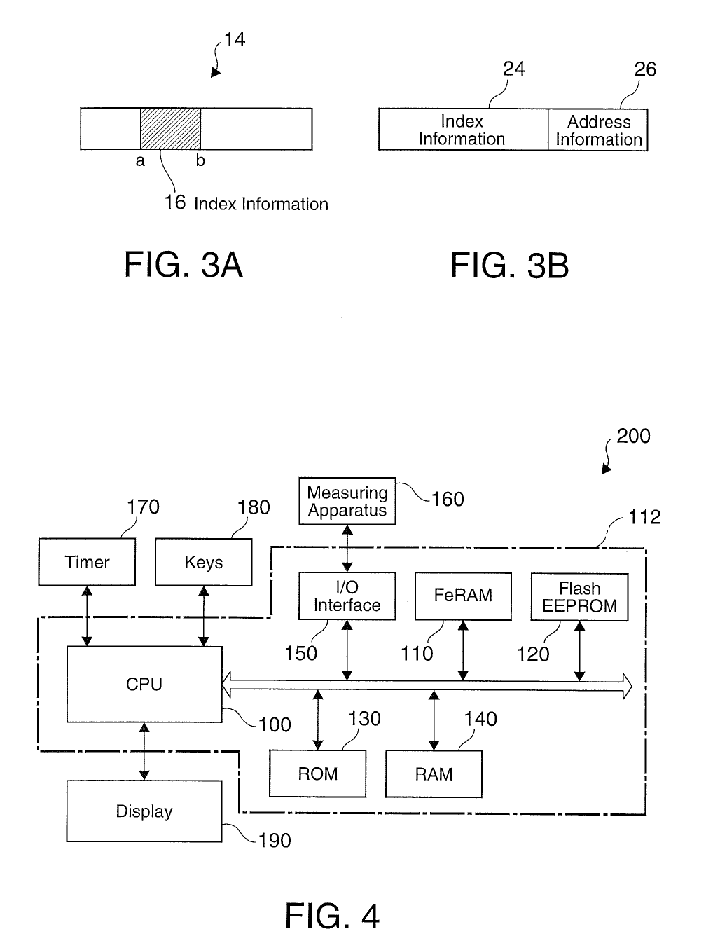

FIG. 2 is a diagram for describing the structure of the first nonvolatile memory section and the second nonvolatile memory section in accordance with the present embodiment. Also, FIGS. 3A and 3B are diagrams for describing data body and index information.

As shown in FIG. 2, each of the first nonvolatile memory section 10 and the second nonvolatile memory section 20 is composed as a ring buffer.

The first nonvolatile memory section 10 has one-dimensionally arranged data areas 12-1, 12-2, 12-3, etc. for data body, in which received data is successively written from the start of the data areas toward the end of the data areas. When the end is reached, the writing operation returns to the start again and the received data is sequentially overwritten. The position of the start may be appropriately set based on logical addresses, and is not limited to the physical start position.

The second nonvolatile memory section 20 has one-dimensionally arranged data areas 22-1, 22-2, 22-3, etc. for index information, in which given information obtained for the received data is used as index information 24, and the index information 24 and write destination address information 26 of the received data are stored as sets, as shown in FIG. 3B.

In other words, the index information corresponding to the data areas 12-1, 12-2, 12-3, etc. of the first nonvolatile memory section 10 are stored in the data areas 22-1, 22-2, 22-3, etc. of the second nonvolatile memory section 20.

As shown in FIGS. 3A and 3B, based on index position information (a, b), given information 16 to be used as index information may be extracted from the received data 14, thereby generating the index information 24. The index position information (a, b) is position information that specifies the given information (information to be extracted as index information) among the received data 14. It is noted that the index position information may be given in a combination of (start position, end position), or a combination of (start position, data size).

According to the present embodiment, from among data received, index information for judging the importance of the data, the necessity as to whether the data is to be permanently stored, or the like is extracted, and stored in the second nonvolatile memory section (ring buffer) 20; and the data body is stored in the first nonvolatile memory section (ring buffer) 10 having a greater storage capacity. In other words, the second nonvolatile memory section (ring buffer) 20 stores only the index information and the address information of the data body.

The second nonvolatile memory section (ring buffer) 20 may be formed from FeRAM that has an excellent long life of re-writing cycles.

In the present embodiment, when necessary data is extracted from the log data stored in the first nonvolatile memory section 10, the necessity of the data is judged according to the index information stored in the second nonvolatile memory section (ring buffer) 20, and the data is extracted from the nonvolatile memory section only when the data is judged to be necessary.

For example, extracting conditions may be set in association with the index information, the index information in the nonvolatile memory section 20 is searched based on the extracting conditions, and those of the index information that satisfy the extracting conditions are extracted. Then, based on the address information 26 stored in association with the index information 24 (in other words, stored with the index information 24 as a set), corresponding data may be read out from the first nonvolatile memory section 10 (in this case, random access readout is performed).

Generally, a memory section with a large storage capacity is needed when the data body is large in size. However, in accordance with the present embodiment, by searching the second nonvolatile memory section 20 with a relatively small storage capacity, data stored in the first nonvolatile memory section 10 with a large storage capacity can be extracted.

When data is imported to a data storage device (a data log device or the like), the importance and the necessity for continuous storage of many of the data are not decided at the time they are imported. Such decisions initially become possible when surrounding conditions of the data are finalized after storing the data for a predetermined period of time. For example, in the case of recording a telephone conversation, only when an action is taken according to the memory of the telephone conversation, ambiguity of the information remembered, insufficiency of the information and the like reveal, and then the recorded telephone conversation may be played back. In other words, the information is now defined as information that needed to be stored. Tentative storage of data until the necessity of storing the data is finalized is expected to expand in future with proliferation of digital data. Furthermore, judgment as to whether tentatively stored data are necessary or not is also an important issue. The process would never be fast enough if a large amount of data is reviewed from end to end to judge their necessity. In order to effectively judge the necessity of data, it is necessary to extract indexes from the data, which enable judgment of the importance of the data, thereby making the judgment. Concretely, for example, in the case of recording a telephone call, its conversation partner, the time and the time duration of the telephone call may be considered as indexes. By using these indexes, telephone call records some of which are necessary to be permanently stored, and the other of which are temporally stored are selected “later,” and they may be transferred depending on the necessity from the tentative memory media (the first nonvolatile memory section 10 in this example) to a permanent memory media.

Next, a concrete device structure of the data storage device 1 in accordance with the present embodiment is described. FIG. 4 is a block diagram of an example of the concrete device structure of the data storage device 1.

A data storage device 200 in accordance with the present embodiment includes flash EEPROM 120. The flash EEPROM 120 functions as a first nonvolatile memory section, and stores data, such as, for example, records of received telephone calls in which the amount of data for each record is large in volume and the size of the volume is not fixed, or data body generated based on measurement data and the like in which the data itself is large in volume and irregularly imported.

The data storage device 200 in accordance with the present embodiment includes FeRAM 110. The FeRAM 110 functions as a second nonvolatile memory section, and stores index information corresponding to the data body, and data body address information.

The data storage device 200 in accordance with the present embodiment includes RAM 140. The RAM 140 is used to store, for example, measurement parameters. The RAM 140 may be formed from EEPROM or FeRAM.

The data storage device 200 in accordance with the present embodiment includes an I/O interface 150 that receives data, such as, for example, records of received telephone calls in which the amount of data for each record is large in volume and the size of the volume is not fixed, or data from a measuring apparatus 160 that obtains measurement data and the like in which the data itself is large in volume and irregularly imported.

The data storage device 200 in accordance with the present embodiment includes ROM 130. The ROM 130 stores a measurement control program or the like.

The data storage device 200 in accordance with the present embodiment includes CPU 100. The CPU 100 performs controls, according to the control program stored in the ROM 130, such as, for example, receiving measurement data irregularly outputted from the measuring apparatus 160 through the I/O interface 150, using measurement parameters inputted through the keys 180, and storing the data in the ring buffer area formed from the flash EEPROM 120; and extracting index information from the measurement data, and storing index data including the index information and write addresses of the measurement data in the ring buffer area formed from the FeRAM 110. Also, the CPU 140 may control a timer 170 and a display 190.

In other words, the CPU 100 functions as the first write control section 30, the second write control section 40 and the index information extracting section 50.

In the data storage device 1, the CPU 100, the FeRAM 110, the flash EEPROM 120, the ROM 130, the RAM 140 and the I/O interface 150 may be composed in a single integrated circuit device (for example, a semiconductor chip). Further, the data storage device 1 may have the integrated circuit device control the measuring apparatus, and control generation of display image data for displaying an image on the display.

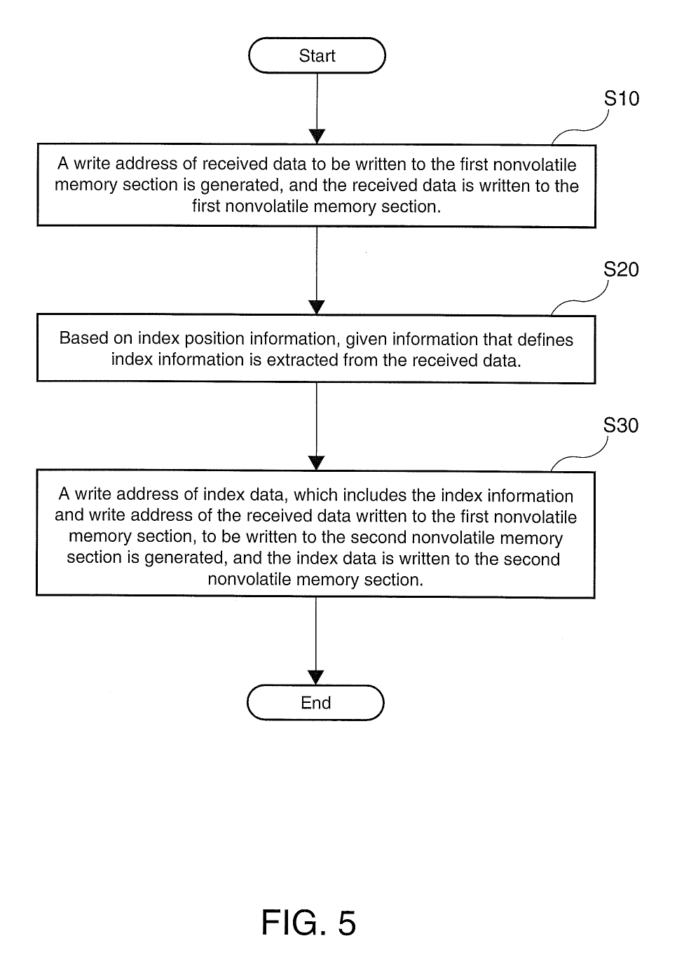

FIG. 5 is a flow chart that describes an example of the operations of the data storage device.

First, a write address of received data to be written to the first nonvolatile memory section is generated, and the received data is written to the first nonvolatile memory section (step S10).

For example, address data of a storage address of measured data this time may be generated based on a storage address of measured data last time+the data size of the measured data last time (an additional size may be added if necessary). The address data generated may be stored in the CPU (for example, in a resister), and may be used as a data storage address of measured data last time when storage address data of measured data next time is generated.

Next, based on index position information, given information that defines index information is extracted from the received data (step S20). The index position information may be set to be externally changeable.

Next, a write address of index data, which includes the index information and write address of the received data written to the first nonvolatile memory section, to be written to the second nonvolatile memory section is generated, and the index data is written to the second nonvolatile memory section (step S30).

According to the present embodiment, it is possible to provide a data storage device that is capable of storing a large amount of data in a readily searchable form, using the ring buffers.

Also, in this embodiment of the invention, the second nonvolatile memory section being formed from ferroelectric memories, index information that becomes unnecessary to be temporarily stored after a predetermined time has elapsed since the time it was written is successively overwritten. Accordingly, although the number of re-writing operations is increased, a relatively small memory area is sufficient for the operations described above, such that information can be readily searched.

The invention is not limited to the embodiments described above, and many modifications can be made. The invention may include compositions that are substantially the same as the compositions described in the embodiments (for example, a composition with the same function, method and result, or a composition with the same object and result). Also, the invention includes compositions in which portions not essential in the compositions described in the embodiments are replaced with others. Also, the invention includes compositions that achieve the same functions and effects or achieve the same objects of those of the compositions described in the embodiments. Furthermore, the invention includes compositions that include publicly known technology added to the compositions described in the embodiments.

What is claimed is:

1. A data storage device comprising:
a first nonvolatile memory section;
a second nonvolatile memory section having a smaller memory capacity than the first nonvolatile memory section;
a first write control section that performs a cyclic write control including sequentially writing received data to one-dimensionally arranged data areas in the first nonvolatile memory section from a start toward an end thereof, and again sequentially writing the received data from the start toward the end upon reaching the end; and
a second write control section that performs a cyclic write control including obtaining given information for the received data as index information, linking the index information to write address information of the received data, sequentially writing the index information to one-dimensionally arranged data areas in the second nonvolatile memory section from a start toward an end thereof, and again sequentially writing the index information from the start toward the end upon reaching the end.

2. A data storage device according to claim 1, further comprising an index information extracting section that extracts the given information as the index information from the received data based on index position information, wherein the second write control section performs a write control with the given information extracted from the received data as the index information.

3. A data storage device according to claim 1, wherein the second nonvolatile memory section is formed from a ferroelectric memory.

4. A method for controlling a data storage device equipped with a first nonvolatile memory section and a second nonvolatile memory section having a smaller memory capacity than the first nonvolatile memory section, the method comprising the steps of:
performing a cyclic write control including sequentially writing received data to one-dimensionally arranged data areas in the first nonvolatile memory section from a start toward an end thereof, and again sequentially writing the received data from the start toward the end upon reaching the end; and
performing a cyclic write control including obtaining given information for the received data as index information, linking the index information to write address information of the received data, sequentially writing the index information to one-dimensionally arranged data areas in the second nonvolatile memory section from a start toward an end thereof, and again sequentially writing the index information from the start toward the end upon reaching the end.
